(19) United States
(12) Patent Application Publication
(10) Pub. No.: US 2008/0185698 A1
(43) Pub. Date: Aug. 7, 2008

(54) SEMICONDUCTOR PACKAGE STRUCTURE AND CARRIER STRUCTURE

(75) Inventors: Yen-Wen Tseng, Taoyuan County (TW); Mei-Lin Hsieh, Taoyuan County (TW); Chih-Hung Hsu, Taipei County (TW); Kuang-Hsiung Chen, Taoyuan County (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/942,496

(22) Filed: Nov. 19, 2007

(30) Foreign Application Priority Data
Feb. 7, 2007 (TW) 96104514

(51) Int. Cl. H01L 23/495; H01L 23/48

(52) U.S. Cl. 257/676; 257/690; 257/E23.031; 257/E23.01

(57) ABSTRACT

A semiconductor package structure is disclosed. The structure comprises a die pad, a chip, leads, a recess, and an encapsulant. The chip is disposed on the die pad. The leads are disposed on a periphery of the die pad and electrically connected to the chip. The recess is formed on the top surface of at least one of the leads and extends to the outside surface thereof. The encapsulant is used for encapsulating the die pad, the chip, the leads, and the recess.

### CROSS-REFERENCE TO RELATED APPLICATION

This application claims the priority benefit of Taiwan application serial no. 96104514, filed on Feb. 7, 2007. The entirety of the above-mentioned patent application is hereby incorporated by reference herein and made a part of this specification.

### BACKGROUND OF THE INVENTION

1. Field of the Invention

The present invention is related to a semiconductor package structure and more particularly to a semiconductor package structure having recess formed on at least one of the leads.

2. Description of Related Art

In the process of manufacturing semiconductors, the integrated circuit (IC) package is one of the important steps used for protecting the IC chips and providing externally electrical connection. An IC lead frame provides a substrate for safely disposing the IC chip, which is able to connect the IC chip with the print circuit board (PCB).

With increasing IC integration level and the demand for high-performance electronic products, the packaging technique is driven toward increasing packaging density, decreasing package sizes and shortening transmission distances to follow the trend of shrinking IC component sizes and continually rising input/output (I/O) counts.

There are many types of IC packages, wherein a common package type initially provides a lead frame having a die pad and a plurality of leads disposed on a periphery the die pad. Next, the chip is attached to the die pad and the leads on a periphery of the die pad by using bumps disposed on the chip. After that, the chip, the die pad and a portion of the leads are encapsulated by a packaging material which fills up the space between the chip and the die pad so as to complete packaging the chip. The packaged chips can be electrically connected with external components via the bumps and the leads.

However, when the chip has been packaged and if the packaging material does not match well with the chips and the leads, the packaging material may peel off, and thus, the packaging quality of the chips and the yield of the final products can be seriously affected.

### SUMMARY OF THE INVENTION

Accordingly, one aspect of the present invention is to provide a semiconductor package structure. With a recess formed on a top surface of a lead and extending to an outside surface thereof, a level of an encapsulant matching with a chip and a carrier is increased so that the packaging quality is enhanced.

Another aspect of the present invention is to provide a carrier structure used for semiconductor packaging. With the recess forming on the top surface of the lead and extending to a junction between the lead and a frame body, the level of the encapsulant matching with the chip and the carrier is increased so that the packaging quality is enhanced.

Still another aspect of the present invention is to provide a semiconductor package structure by which the abrasion of a cutting tool is mitigated while cutting the frame body so that the lifespan of the cutting tool is prolonged.

According to an embodiment of the present invention, the semiconductor package structure of the present invention at least includes a die pad, a chip, leads, recesses and an encapsulant. The chip is disposed on the die pad. The leads are disposed on a periphery of the die pad and electrically connected with the chip. Each of the leads has a top surface and an outside surface, and the outside surface is relatively far from the chip. The recesses are formed on the top surfaces of the leads and extend to the outside surfaces thereof. The encapsulant encapsulates the die pad, the chip, the leads and the recesses.

Furthermore, according to an embodiment of the present invention, the carrier structure used for semiconductor packaging in the present invention at least includes a frame body, a lead and a recess. The lead is connected with the frame body, wherein the lead has a top surface. The recess is formed on the top surface of at least one of the leads and extends to a junction between the lead and the frame body.

In addition, according to an embodiment of the present invention, the frame body of the carrier structure used for semiconductor packaging has a plurality of packaging areas used for forming a plurality of semiconductor package structures after the frame body has been cut off.

Therefore, in the semiconductor package structure of the present invention, the recess is formed on the top surface of at least one of the leads on the carrier and extends to the junction between the lead and the frame body. When the semiconductor package structure of the present invention has been completed, the recess extends to the outside surface of the lead so as to increase the level of the encapsulant matching with the chip and the carrier so that the packaging quality and the yield are enhanced. The recess can reduce the abrasion of a cutting tool while cutting the frame body so that the lifespan of the cutting tool is prolonged.

### BRIEF DESCRIPTION OF THE DRAWINGS

In order to make the above and other objects, features and advantages of the present invention more comprehensible, several embodiments accompanied with figures are described in detail below.

FIG. 1 is a schematic side view illustrating a semiconductor package structure according to the first embodiment of the present invention.

FIG. 2 is a schematic top view illustrating a carrier of the semiconductor package structure according to the first embodiment of the present invention.

FIG. 3 is a local three-dimensional view illustrating a portion of the carrier of the semiconductor package structure according to the first embodiment of the present invention.

FIG. 4 is a schematic cross-sectional view illustrating a single lead of the semiconductor package structure according to the first embodiment of the present invention.

FIG. 5 is a schematic cross-sectional view illustrating a single lead of the semiconductor package structure according to the second embodiment of the present invention.

FIG. 6 is a schematic cross-sectional view illustrating a single lead of the semiconductor package structure according to the third embodiment of the present invention.

FIG. 7 is a schematic top view illustrating a single lead of the semiconductor package structure according to the third embodiment of the present invention.

FIG. 8 is a schematic top view illustrating the semiconductor package structure according to the fourth embodiment of the present invention.

FIG. 9 is a schematic side view illustrating the semiconductor package structure according to the fifth embodiment of the present invention.

### DESCRIPTION OF EMBODIMENTS

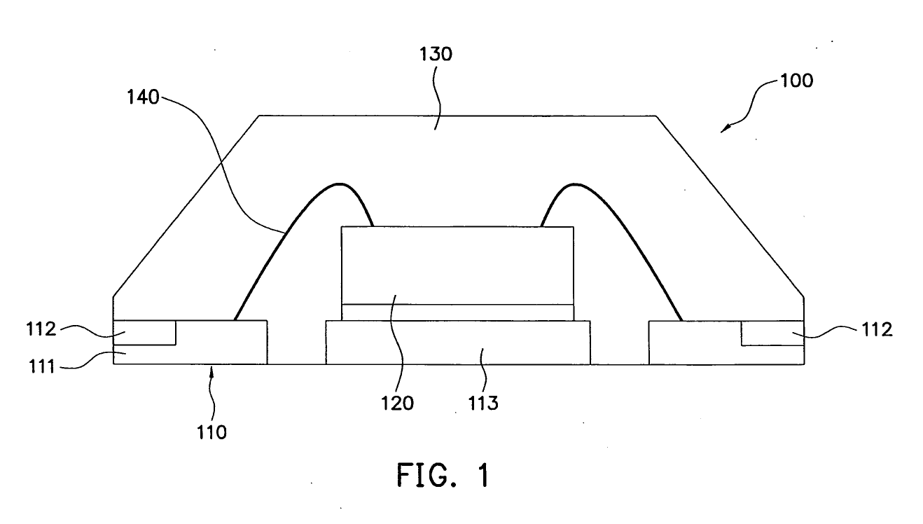

Referring to FIG. 1, it is a schematic side view illustrating a semiconductor package structure according to the first embodiment of the present invention. A semiconductor package structure 100 of the present embodiment includes a carrier 110, a chip 120 and an encapsulant 130. The carrier 110 is use for carrying the chip 120, and the encapsulant 130 is used for encapsulating the chip 120 and the carrier 110 so that the semiconductor package structure 100 of the present embodiment is formed. In addition, the semiconductor package structure 100 of the present embodiment can be, for example, but not limited to, a quad flat no-lead (QFN) package structure and other package structures having external leads are also suitable for the semiconductor package structure 100 of the present embodiment.

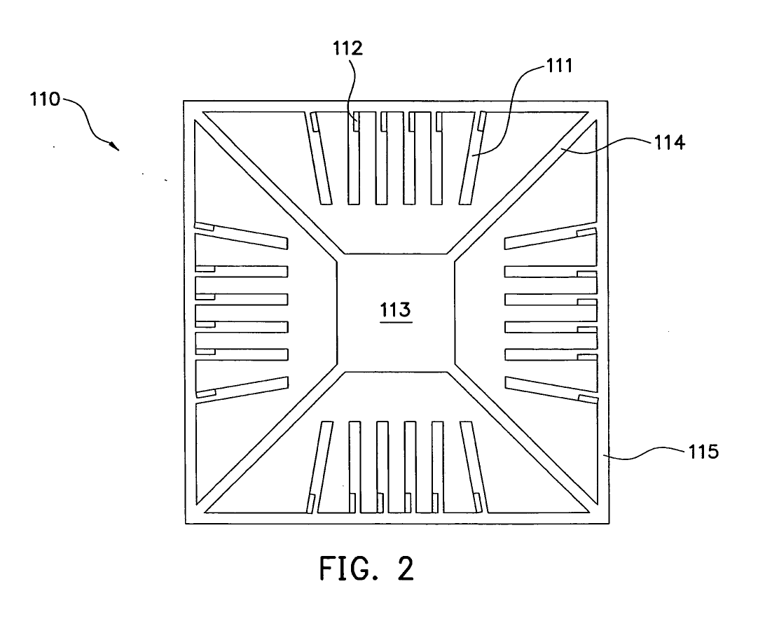

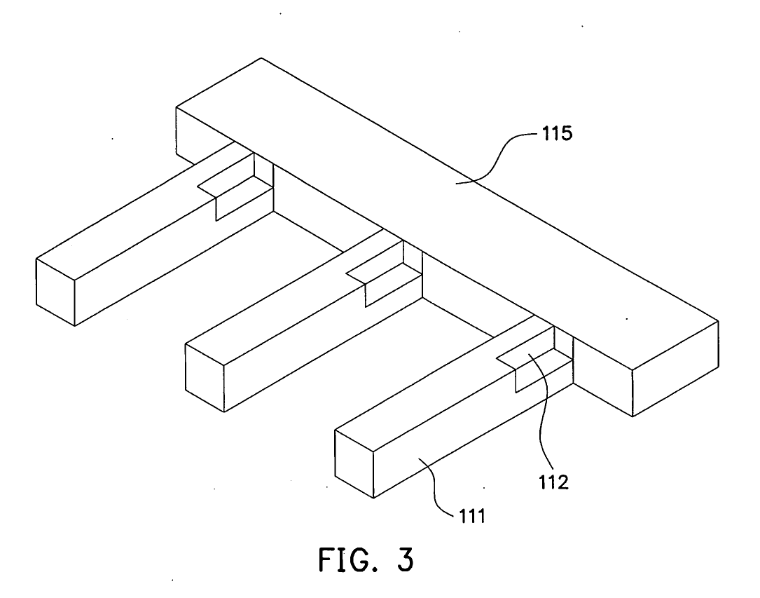

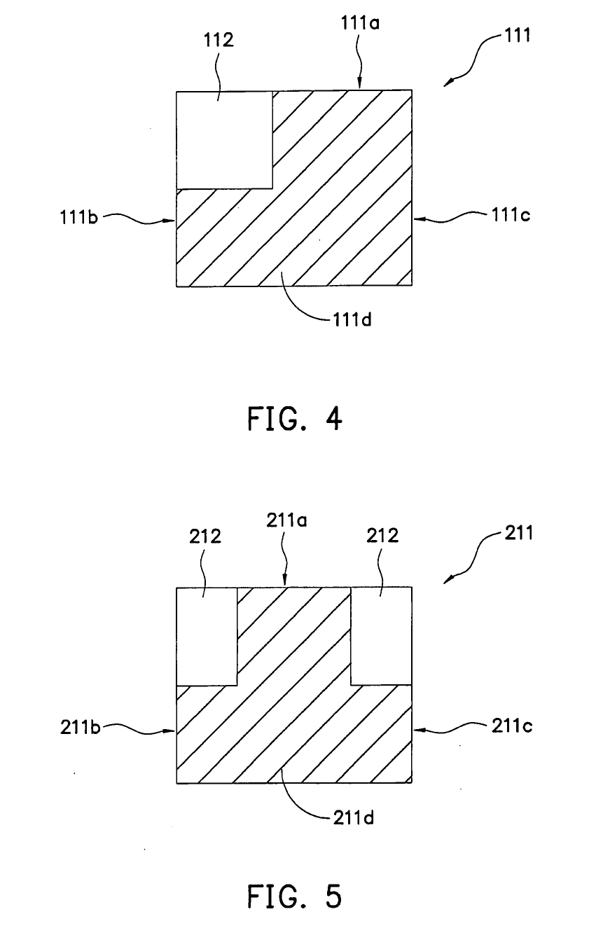

Referring to FIGS. 2 through 4, FIG. 2 is a schematic top view illustrating a carrier of the semiconductor package structure according to the first embodiment of the present invention. FIG. 3 is a three-dimensional view illustrating a portion of the carrier of the semiconductor package structure according to the first embodiment of the present invention. FIG. 4 is a schematic cross-sectional view illustrating a single lead of the semiconductor package structure according to the second embodiment of the present invention. The carrier 110 of the present embodiment is, for example, a lead frame made of high conductive materials such as silver, gold, aluminum, copper and any alloy thereof. The lead frame includes a plurality of leads 111, at least one recess 112, a die pad 113 and at least one supporting bar 114 and a frame body 115. The leads 111 are respectively connected with the frame body 115 (a rectangular frame body, for example) and disposed at the inner part of a periphery of the frame body 115. Each of the leads 111 has a top surface 111a, a first side surface 111b and a second side surface 111c. The first side surface 111b and the second side surface 111c are respectively adjacent to the top surface 111a. The recess 112 is formed on the top surface 111a of at least one of the leads 111 and extends to a junction between the lead 111 and the frame body 115. The recess 112 is formed at a corner formed by the first side surface 111b and the top surface 111a or by the second side surface 111c and the top surface 111a. The recess 112 is formed by, for example, an etching, laser etching or punching method to form a recess in a rectangular, arc or irregular shape, for example. The die pad 113 is disposed in the center position of the carrier 110 and connected with the frame body 115 via the supporting bars 114 to carry the chip 120. The supporting bars 114, for example, are disposed at four corners of the frame body 115 to connect with the die pad 113 firmly.

As shown in FIG. 1, when a packaging process is performed according to the present embodiment, initially, the chip 120 is adhered on the die pad 113 of the carrier 110. Next, an electrical connection is formed between the chip 120 and the leads 111 of the carrier 110. In the present embodiment, the chip 120 is electrically connected with the leads 111 via a plurality of conductive wires 140, for example. Then, the encapsulant 130 is used for encapsulating the chip 120 and the carrier 110 to form a unity, wherein the encapsulant 130 at least encapsulates until the recess 112 of the lead 111 and increases the level of the encapsulant 130 matching with the chip 120 and the carrier 110 via the recess 112 of the lead 111. After that, a cutting-off step is performed to cut off the frame body 115 of the carrier 110 so as to form the semiconductor package structure 100 of the present embodiment. Meanwhile, since the recess 112 extends to the junction between the lead 111 and the frame body 115, the recess 112 of the lead 111 can further reduce the cutting area of a cutting tool (not shown) so that the abrasion of the cutting tool can be mitigated.

It should be noted that the encapsulant 130 of the semiconductor package structure 100 in the present embodiment can totally encapsulate the recess 112 or, alternatively, encapsulate a portion of the recess 112 and expose a portion of the recess 112.

As shown in FIGS. 1, 3 and 4, after the semiconductor package structure 100 is completed, the frame body 115 of the carrier 110 has been cut off. Therefore, each of the leads 111 of the present embodiment has an outside surface 111d respectively. The recess 112 of the lead 111 is formed on the top surface 111a of the lead 111 and extends to the outside surface 111d. Thus, the encapsulant 130 can firmly encapsulate the chip 120 and the carrier 110 via the recess 112 of the lead 111 so as to prevent the encapsulant 130 from peeling off due to the bad matching level of the encapsulant 130 so that the packaging quality and the yield are enhanced.

Referring to FIG. 5, it is a schematic cross-sectional view illustrating a single lead of the semiconductor package structure according to the second embodiment of the present invention. In comparison with the first embodiment, each of the leads 211 of the semiconductor package structure 100 in the second embodiment has two recesses 212. The recesses 212 are respectively formed on two corners respectively formed by a first side surface 211b and a top surface 211a and by a second side surface 211c and the top surface 211a respectively, which extends to an outside surface 211d of the lead 211. Therefore, the recesses 212 of the lead 211 in the second embodiment can further increase the matching level of the encapsulant 130 so that the semiconductor package structure 100 can be firmer.

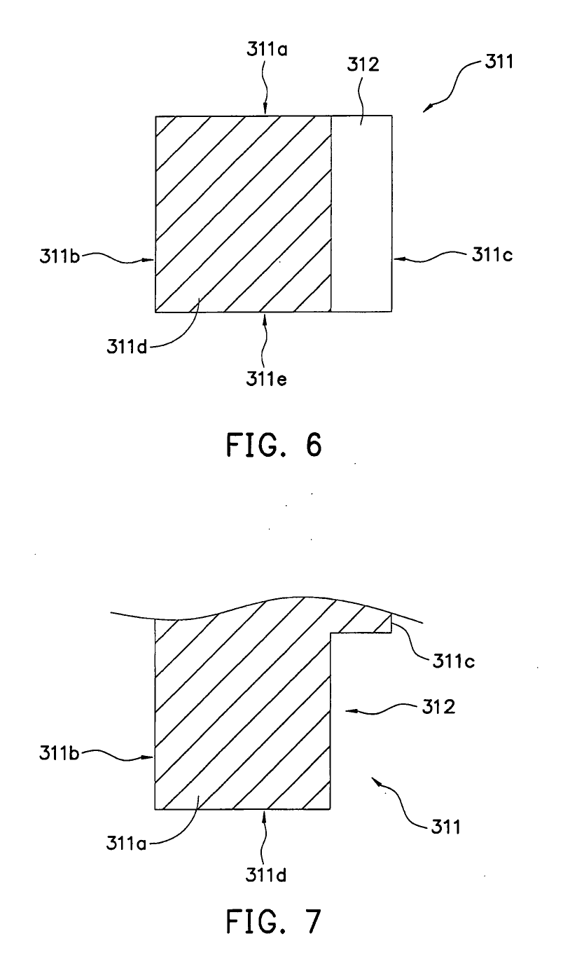

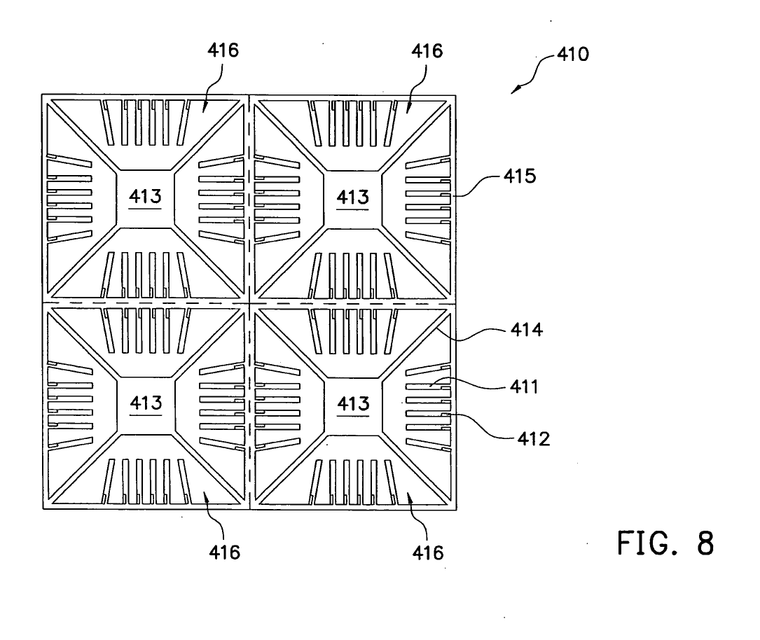

Referring to FIGS. 6 and 7, FIG. 6 is a schematic cross-sectional view illustrating a single lead of the semiconductor package structure according to the third embodiment of the present invention, while FIG. 7 is a schematic cross-sectional view illustrating a single lead of the semiconductor package structure according to the third embodiment of the present invention. In comparison with the first embodiment, a recess 312 of each leads 311 in the third embodiment is formed at two corners formed by a first side surface 311b and a top surface 311a or, alternatively, by a second side surface 311c and the top surface 311a of the lead 311, and extends to an outside surface 311d of the lead 311. The recess 312 has a depth to a bottom surface 311e of the lead 311 so as to increase the matching level of the encapsulant 130.

Referring to FIG. 8, it is a schematic top view illustrating the semiconductor package structure according to the fourth embodiment of the present invention. In comparison with the first embodiment, a carrier 410 of the fourth embodiment has a plurality of leads 411, a plurality of recesses 412, a plurality of die pads 413, a plurality of supporting bars 414, a frame body 415 and a plurality of package areas 416. The package areas 416 are defined by the frame body 415. In the meantime, the leads 411 are respectively disposed at the inner parts of peripheries of the package areas 416. The recesses 412 extend to a junction between the leads 411 and the frame body 415. The die pads 413 are respectively disposed in center positions of the package areas 416 and connected with the frame body 415 via the supporting bars 414. Meanwhile, the package areas 416 can carry a plurality of chips 120 and forms a plurality of semiconductor package structures 100 when the encapsulant 130 is encapsulated and the frame body 415 is cut off.

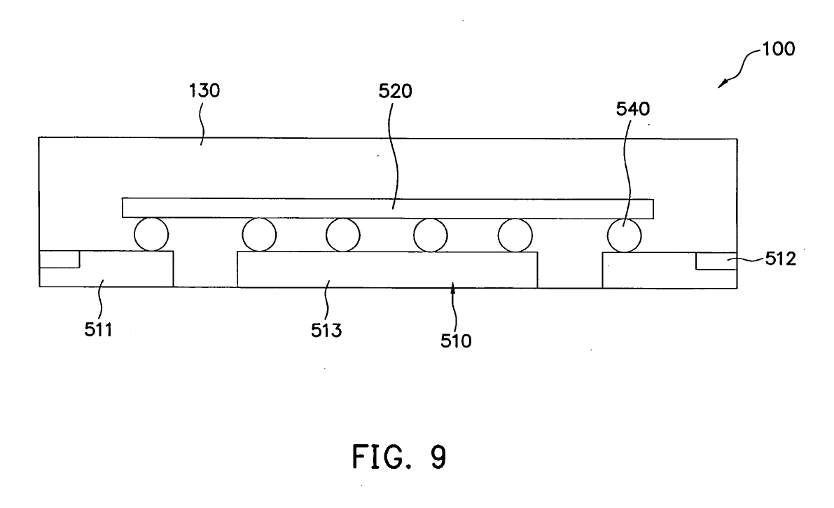

Referring to FIG. 9, it is a schematic side view illustrating the semiconductor package structure according to the fifth embodiment of the present invention. In comparison with the first embodiment, a chip 520 of the fifth embodiment is connected with leads 511 and a die pad 513 of a carrier 510 via a plurality of bumps 540 by a flip chip (FC) technique and electrically connected with the leads 511. Recesses 512 are formed on the leads 511 to increase the matching level of the encapsulant 130.

It can be known from the above-mentioned embodiments of the present invention that in the semiconductor package structure of the present invention, a recess is formed on the top surface of at least one of the leads and extends to the junction between the leads and the frame body. When the semiconductor package structure of the present invention is completed (after the frame body of the carrier is cut off), the recess extends to the outside surface of the lead to increase the level of the encapsulant matching with the chip and the carrier so that the packaging quality and the yield are enhanced. In addition, the abrasion of the cutting tool can be further mitigated by the recess while cutting the frame body.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor package structure, at least comprising:
a die pad;
at least one chip disposed on the die pad;
a plurality of leads disposed on a periphery of the die pad and electrically connected with the chip, wherein each of the leads has a top surface and an outside surface, and the outside surface is relatively far from the chip;
at least one recess formed on the top surface of at least one of the leads, which extends to the outside surface; and
an encapsulant encapsulating the die pad, the chip, the leads and the recess.

2. The semiconductor package structure of claim 1, wherein the semiconductor package structure is a quad flat no-lead (QFN) package structure.

3. The semiconductor package structure of claim 1, wherein a portion of the recess is exposed by the encapsulant.

4. The semiconductor package structure of claim 1, wherein the leads is electrically connected with the chip via a plurality of conductive wires.

5. The semiconductor package structure of claim 1, wherein the chip is electrically connected with the leads via a plurality of bumps.

6. The semiconductor package structure of claim 1, further comprising:
at least one supporting bar connected with the die pad.

7. The semiconductor package structure of claim 1, wherein each of the leads further comprises a first side surface and a second side surface, wherein the first side surface is opposite to the second side surface, the first side surface and the second side surface are respectively adjacent to the top surface and the outside surface, wherein the recess is formed at a corner formed by the first side surface and the top surface.

8. The semiconductor package structure of claim 7, wherein another recess is formed at another corner formed by the second side surface and the top surface of each of the leads.

9. The semiconductor package structure of claim 7, wherein the recess has a depth to a bottom surface of the lead.

10. The semiconductor package structure of claim 1, wherein the recess has a rectangle shape.

11. The semiconductor package structure of claim 1, wherein the recess has an arc shape.

12. The semiconductor package structure of claim 1, wherein the recess has an irregular shape.

13. A carrier structure used for semiconductor packaging, at least comprising:
a frame body;
a plurality of leads connected with the frame body, wherein each of the leads has a top surface; and
at least one recess formed on the top surface of at least one of the leads, which extends to a junction between the lead and the frame body.

14. The carrier structure used for semiconductor packaging of claim 13, at least further comprising:
a die pad, wherein the leads are on a periphery of the die pad.

15. The carrier structure used for semiconductor packaging of claim 13, at least further comprising:
at least one supporting bar connected with the die pad.

16. The carrier structure used for semiconductor packaging of claim 13, wherein each of the leads further comprises a first side surface and a second side surface, wherein the first side surface is opposite to the second side surface, the first side surface and the second side surface are respectively adjacent to the top surface and the outside surface, wherein the recess is formed at a corner formed by the first side surface and the top surface.

17. The carrier structure used for semiconductor packaging of claim 16, wherein another recess is formed at another corner formed by the second side surface and the top surface of each of the leads.

18. The carrier structure used for semiconductor packaging of claim 13, wherein the recess has a depth to a bottom surface of the lead.

19. The carrier structure used for semiconductor packaging of claim 13, wherein the recess has a rectangle shape.

20. The carrier structure used for semiconductor packaging of claim 13, wherein the recess has an arc shape.

21. The carrier structure used for semiconductor packaging of claim 13, wherein the recess has an irregular shape.
